(19) United States
(12) Patent Application Publication
(10) Pub. No.: US 2005/0007134 A1
(43) Pub. Date: Jan. 13, 2005

(54) Probe card

(75) Inventor: Yoshinori Deguchi, Hyogo (JP)

Correspondence Address: McDermott, Will & Emery, 600 13th Street, N.W., Washington, DC, 20005-3096, US

(73) Assignee: Renesas Technology Corp.

(21) Appl. No.: 10/885,721

(22) Filed: Jul. 8, 2004

(30) Foreign Application Priority Data
Jul. 8, 2003 (JP) 2003-193363

(51) Int. Cl. G01R 31/02

(52) U.S. Cl. 324/756

(57) ABSTRACT

A probe card has a tip portion of a probe needle having a flat shape and an area of 78.5 μm² or larger. The probe card also has load setting means for setting a load to the tip portion to be 80 kgf/mm² or lower when the tip portion is pressed against an electrode pad, and intersection angle setting means for setting an intersection angle of a plane of the electrode pad with a plane of the tip portion to be 2° or smaller when the tip portion is pressed against the electrode pad. With this, a probe card that decreases damage to an electrode pad and an interlayer insulation film of a lower layer, suppresses generation of a crack and enables highly reliable testing of a semiconductor device can be provided.

### BACKGROUND OF THE INVENTION

1. Field of the Invention

The present invention relates to a probe card. More specifically, the present invention relates to an improvement in a device structure of a probe card.

2. Description of the Background Art

A probe card is used for a test to check electric characteristics of a semiconductor integrated circuit (a wafer test), a display test for a display device, an operation test for an electronic circuit substrate, and other tests for a semiconductor device. To perform an operation test for a semiconductor device, a tip portion of a probe needle of the probe card is pressed against an electrode pad of the semiconductor device to make electric contact of the tip portion of the probe needle with the electrode pad.

When the probe needle is pressed against the electrode pad in an operation test using a conventional probe card, it is known that a crack is generated in an interlayer insulation film located below the electrode pad. The crack, however, caused no problem in a conventional semiconductor device, because a wiring layer was not provided below the interlayer insulation film.

In these days, many of semiconductor devices having large scale packages using a flip chip bonding technology adopt structures such as a cross-sectional view shown in FIG. 6. That is, an electrode pad 21 protected with a polyimide film 26 is arranged above an active element region having stacked wiring layers 23, 24, with an interlayer insulation film 22 interposed therebetween.

When a probe needle 11 is pressed against electrode pad 21 of the semiconductor device having such structure during the operation test using the probe card, the semiconductor device including electrode pad 21 is pushed up to probe needle 11 for a certain distance (over drive), and thus probe needle 11 is pressed while moving on a surface of electrode pad 21 (in a direction h in FIG. 6).

As a result, electrode pad 21 deforms to a lower layer side and in the moving direction of probe needle 11, and a crack 4 is generated in interlayer insulation film 22 below electrode pad 21, which breaks electrical insulation capability between electrode pad 21 and wiring layer 23. Therefore, a circuit of the semiconductor device does not function, resulting in decreased reliability of the semiconductor device and decreased yields in manufacturing steps.

The problem becomes more significant when a silicon oxide film doped with fluorine is used as a low-permittivity film for interlayer insulation film 22 to avoid increase in delay of wiring signal speed, as the semiconductor device is made smaller.

Furthermore, the problem is not limited to the semiconductor device having a large scale package using the flip chip bonding technology. As the structure of arranging an electrode pad above an active element region having a wiring layer with an interlayer insulation film interposed therebetween is also adopted for size reduction of a chip, SiP (System In Package) purpose and the like, similar problem occurs.

When a generally-used probe card called cantilever type is used, as the tip portion of the probe needle forms a large angle with the electrode pad during the test, a contact area of the tip portion of the probe needle and the electrode pad is small, and a load at an effective contact area is increased. When a probe card called vertical type is used, a load at a contact area is large because a load is increased to ensure contact stability.

As a result, though either type can decrease damage to the electrode pad and the interlayer insulation film and suppress generation of the crack by decreasing an amount of over drive, a test for the semiconductor device based on a stable electric contact, which is an original purpose, cannot be performed with high reliability.

### SUMMARY OF THE INVENTION

An object of the present invention is to solve the above-described problem, that is, to provide a probe card that decreases damage to an electrode pad and an interlayer insulation film of a lower layer, suppresses generation of a crack and enables highly reliable testing of a semiconductor device.

A probe card according to the present invention is a probe card for performing a performance test for a semiconductor device by pressing a tip portion of a probe needle against an electrode pad of the semiconductor device to make electric contact of the tip portion of the probe needle with the electrode pad, wherein the tip portion of the probe needle has a flat shape having an area of 78.5 μm² or larger. The probe card includes load setting means for setting a load to the tip portion of the probe needle to be 80 kgf/mm² or lower when the tip portion of the probe needle is pressed against the electrode pad, and intersection angle setting means for setting an intersection angle of a plane of the electrode pad with a plane of the tip portion of the probe needle to be 2° or smaller when the tip portion of the probe needle is pressed against the electrode pad.

When a semiconductor device is tested using the probe card having a structure as described above, damage to the electrode pad and the interlayer insulation film of the lower layer can be decreased while ensuring a sufficient pressing force to the electrode pad. As a result, generation of a crack in the interlayer insulation film of the lower layer is suppressed, which ensures reliability of the semiconductor device and can increase yields in manufacturing steps.

With the probe card according to the present invention, a probe card that decreases damage to an electrode pad and an interlayer insulation film of a lower layer, suppresses generation of a crack and enables highly reliable testing of a semiconductor device can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1A is an enlarged schematic diagram of a tip region of a probe needle, showing a situation wherein the probe needle is brought in contact with an electrode pad in a test for a semiconductor device using a probe card in an embodiment. FIG. 1B shows a shape of a tip portion of the probe needle, when the probe needle is seen from the tip side.

FIG. 2 shows a result of a simulation of a tensile stress (kgf/mm²) generated in an interlayer insulation film (an oxide film) below the electrode pad.

FIG. 3 shows a relation between a load and a value of resistance.

FIG. 4 shows a relation between an amount of over drive and a value of resistance.

FIG. 5 shows whether a crack is generated or not in the interlayer insulation film (the oxide film) below the electrode pad with a certain number of contact times of the probe card as well as a conventional probe card with the electrode pad.

FIG. 6 is a schematic diagram showing a problem in the conventional probe card.

### DESCRIPTION OF THE PREFERRED EMBODIMENT

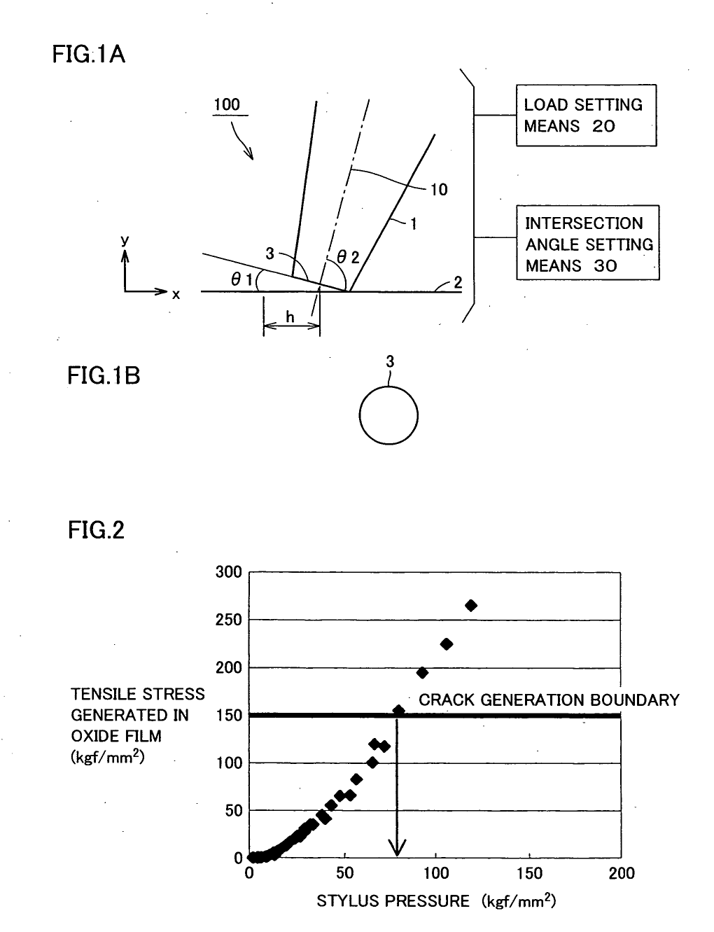

A probe card 100 in an embodiment of the present invention will now be described referring to FIGS. 1A and 1B.

A probe needle 1 in the embodiment has a tip portion 3 of a flat surface having an area of about 78.5 μm². When the tip portion of the probe needle has a circular shape as shown in FIG. 1B, it corresponds to a circle of Φ10 μm in diameter. It is to be noted that, the shape of the tip portion of the probe needle is not limited to a circle, but a shape such as an ellipse is also adoptable, provided that the shape is flat and has an area of 78.5 μm² or larger. For stability of electric contact with an electrode pad 2, the flat area is preferably set within a range between 78.5 μm² and 315 μm² (when it is a circle, it corresponds to Φ20 μm in diameter) for a reason described below.

In a general logic integrated semiconductor device, electrode pad 2 has a film thickness of approximately 0.6 μm-1.5 μm and is made of Al—Cu.

In probe card 100 of this embodiment, a load (pressing force) and an attitude of probe needle 1 having an above-described structure are controlled using load setting means 20 and intersection angle setting means 30.

Load setting means 20 controls a load to the tip portion of probe needle 1 to be 80 kgf/mm² or lower when the tip portion of probe needle 1 is pressed against electrode pad 2 (which corresponds to 6 g/pin or lower when the tip portion of probe needle 1 is Φ10 μm). For stability of electric contact with the electrode pad, the load is preferably controlled to be within a range between 12 kgf/mm² and 80 kgf/mm².

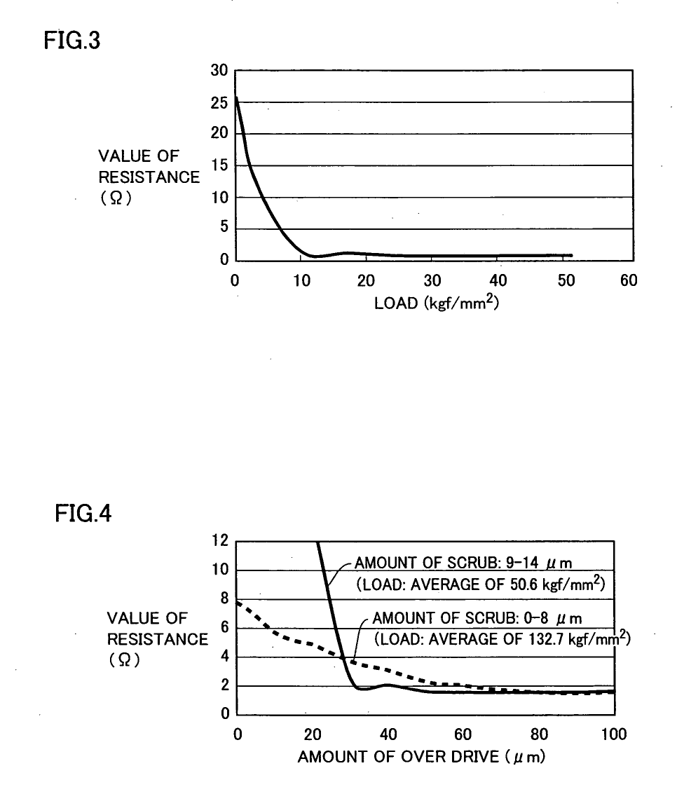

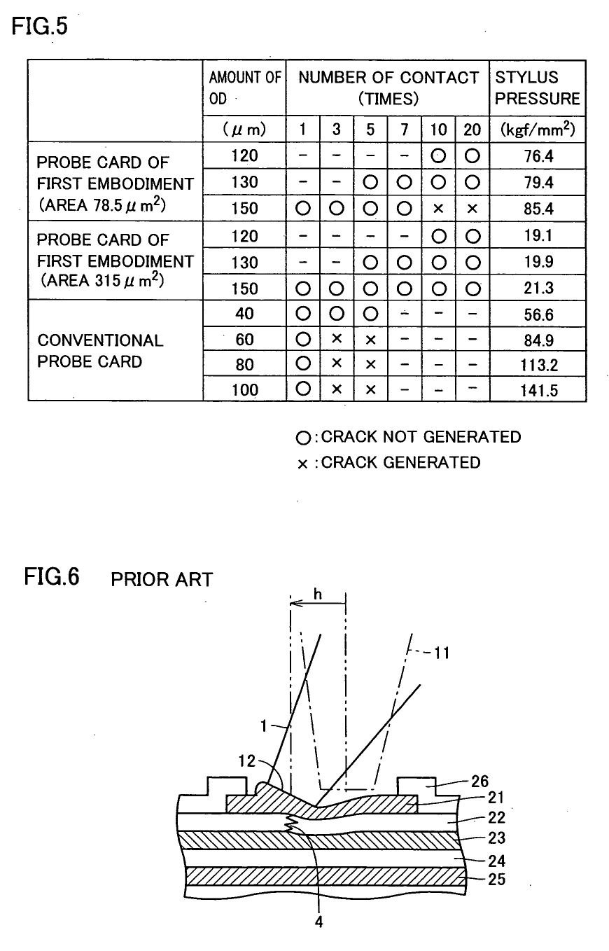

FIG. 2 shows a result of a simulation of a tensile stress (kgf/mm²) generated in an interlayer insulation film (an oxide film) below the electrode pad. When a tensile stress of about 150 kgf/mm² or higher is generated in the interlayer insulation film (the oxide film) below the electrode pad, generation of a crack in the interlayer insulation film is expected. Therefore, referring to FIG. 2, it is apparent that the load (stylus pressure) to probe needle 1 is preferably about 80 kgf/mm² or lower. In addition, from the relation between a value of resistance (Ω) and a load (kgf/mm²) shown in FIG. 3, the load is preferably 12 kgf/mm² or higher.

As a mechanism of load setting means 20 can be implemented with a mechanism applied to a conventional probe card, a detailed description thereof is not given here.

Intersection angle setting means controls an intersection angle (θ1) of a plane of electrode pad 2 with a plane of tip portion 3 of probe needle 1 to be 2° or smaller (within a range 0°-2°) when tip portion 3 of probe needle 1 is pressed against electrode pad 2, as shown in FIGS. 1A and 1B. As to an intersection angle (θ2) of an axis 10 of probe needle 1 with a plane of electrode pad 2, the angle is controlled to be within a range 88°-92°. As a mechanism of intersection angle setting means 30 can be implemented with a mechanism applied to a conventional probe card, a detailed description thereof is not given here.

To test a semiconductor device using probe card 100 having a structure as described above, when the test is performed for a wafer, probe needle 1 makes electric contact with electrode pad 2, then a certain amount of pushing-up (in a direction y in FIG. 1A) load is applied to the wafer (over drive (OD) or over travel) by load setting means 20 to ensure stable contact before performing the test. In this step, as described above, intersection angle (θ1) of a plane of electrode pad 2 with a plane of tip portion 3 of probe needle 1 is controlled to be 2° or smaller (within a range 0°-2°) by the intersection angle setting means.

When the over drive is provided to the wafer, tip portion 3 of probe needle 1 moves along the plane of electrode pad 2 (in a direction x in FIG. 1A). Load setting means 20 controls an amount of this displacement (h: an amount of scrub) to be 10 μm or larger. The amount of 10 μm or larger is preferable because the tip portion is brought into electrical conduction after 50% or more of the tip portion moves to a new surface and, to ensure stability of the contact, 10 μm or larger amount is needed. FIG. 4 shows a situation wherein the contact is not stable even when a large load is applied.

A result of a test for a semiconductor device in a condition described above is described referring to FIG. 5. FIG. 5 shows whether a crack is generated or not in the interlayer insulation film (the oxide film) below the electrode pad with a certain number of contact times of the probe card as well as a conventional probe card with the electrode pad. Situations wherein the tip portions of probe card 1 have areas of 78.5 μm² and 315 μm² are shown.

For the conventional probe card, conditions [amount of over drive (OD) (μm), stylus pressure (kgf/mm²)] of [40 (μm), 56.6 (kgf/mm²)], [60 (μm), 84.9 (kgf/mm²)], [80 (μm), 113.2 (kgf/mm²)], and [100 (μm), 141.5 (kgf/mm²)] were examined. In each of the conditions [60 (μm), 84.9 (kgf/mm²)], [80 (μm), 113.2 (kgf/mm²)] and [100 (μm), 141.5 (kgf/mm²)], generation of a crack in the interlayer insulation film (the oxide film) of the lower layer was recognized when the number of contact times was three. In the condition [40 (μm), 56.6 (kgf/mm²)], generation of a crack in the interlayer insulation film (the oxide film) of the lower layer was not recognized when the number of contact times was up to five.

For the probe card according to this embodiment in the condition as described above, referring to FIG. 5, when the area of the tip portion of probe needle 1 was 78.5 μm², generation of a crack in the interlayer insulation film (the oxide film) of the lower layer was recognized when the number of contact times was 10 in a condition [amount of over drive (OD) (μm), stylus pressure (kgf/mm²)] of [150 (μm), 85.4 (kgf/mm²)]. In each of conditions [130 (μm), 79.4 (kgf/mm²)] and [120 (μm), 76.4 (kgf/mm²)], however, generation of a crack in the interlayer insulation film (the oxide film) of the lower layer was not recognized even when the number of contact times was 20.

Furthermore, when the area of the tip portion of probe needle 1 was 315 μm², generation of a crack in the interlayer insulation film (the oxide film) of the lower layer was not recognized in any condition.

With the result of the simulation shown in FIG. 2 and the experiment data shown in FIGS. 3 to 5, when the area of the tip portion of probe needle 1 is between 78.5 μm² and 315 μm², generation of a crack in the interlayer insulation film (the oxide film) can be avoided if a load (stylus pressure) to probe needle 1 is approximately 80 kgf/mm² or lower.

Although the present invention has been described and illustrated in detail, it is clearly understood that the same is by way of illustration and example only and is not to be taken by way of limitation, the spirit and scope of the present invention being limited only by the terms of the appended claims.

1. A probe card for performing a performance test for a semiconductor device by pressing a tip portion of a probe needle against an electrode pad of the semiconductor device to make electric contact of the tip portion of said probe needle with said electrode pad, comprising:
load setting means for setting a load to the tip portion of said probe needle to be 80 kgf/mm² or lower when the tip portion of said probe needle is pressed against said electrode pad;
intersection angle setting means for setting an intersection angle of a plane of said electrode pad with a plane of the tip portion of said probe needle to be 2° or smaller when the tip portion of said probe needle is pressed against said electrode pad; and
the tip portion of said probe needle including a flat shape having an area of 78.5 μm² or larger.

2. The probe card according to claim 1, wherein
the tip portion of said probe needle has a flat shape having an area from 78.5 μm² to 315 μm², and
said load setting means controls a load to the tip portion of said probe needle to be from 12 kgf/mm² to 80 kgf/mm², and controls an amount of displacement of the tip portion of said probe needle on the plane of said electrode pad to be 10 μm or larger.
